(19) United States
(12) Patent Application Publication
(10) Pub. No.: US 2018/0337713 A1
(43) Pub. Date: Nov. 22, 2018

(54) TECHNIQUES FOR MU-MIMO RATE ADAPTATION

(71) Applicant: QUALCOMM Incorporated, San Diego, CA (US)

(72) Inventors: Ahmed Ragab ELSHERIF, San Jose, CA (US); Srinivas KATAR, Fremont, CA (US)

(21) Appl. No.: 15/600,027

(22) Filed: May 19, 2017

(51) Int. Cl. H04B 7/0452; H04L 1/00; H04B 7/0417; H03M 13/15; H04B 7/04; H04L 5/14; H03M 13/23

(52) U.S. Cl. CPC H04B 7/0452; H04L 1/0003; H04B 7/0417; H03M 13/23; H04B 7/0478; H04L 5/1453; H03M 13/151

(57) ABSTRACT

The present disclosure provides techniques for rate adaptation in multi-user multiple-input-multiple-output (MU-MIMO) systems for wireless local area networks (WLANs). When rate adaptation is based solely on packet error rate (PER) from feedback provided by wireless stations (STAs), the rate selection may not be optimal. In some scenarios, rate adaptation from the combined use of PER and MU signal-to-interference-plus-noise ratio (MU-SINR) can allow for better selection of the rate components, such as modulation coding scheme (MCS) and number of spatial streams (Nss). Accordingly, the present disclosure provides techniques in which a condition associated with transmitting an MU PLCP Protocol Data Unit (MU-PPDU) for multiple STAs is identified, packet error (e.g., PER) and signal strength (e.g., MU-SINR) metrics are determined for each STA in response to such condition, a rate for each STA is determined based on the respective metrics, and the MU-PPDU is transmitted according to the determined rates.

### BACKGROUND

The present disclosure relates generally to wireless communications systems, and more particularly, to techniques for multi-user multiple-input-multiple-output (MU-MIMO) rate adaptation in wireless communications systems.

The deployment of wireless local area networks (WLANs) in the home, the office, and various public facilities is commonplace today. Such networks typically employ an access point (AP) that connects a number of wireless stations (STAs) in a specific locality (e.g., home, office, public facility, etc.) to another network, such as the internet or the like. A set of STAs can communicate with each other through a common AP in what is referred to as a basic service set (BSS). As the number of STAs deployed in such networks grows, techniques that provide more effective MU-MIMO communications are desirable.

For example, there is a need for improvements in the operation of rate adaptation mechanisms to more effectively perform MU-MIMO communications between an AP and its associated STAs. Current rate adaptation mechanisms are typically based on packet error rate (PER) measurements made at the AP from information provided by STAs in the form of block acknowledgments (BAs) after the transmission of packets. Errors in the transmission of MU-MIMO packets can happen for multiple reasons. One reason can be collision on the wireless medium. Another reason can be channel degradation due to Doppler impact caused by AP and/or STA movement. Yet another reason can be channel correlation among STAs in an MU-MIMO physical layer convergence procedure protocol data unit (PLCP PDU or PPDU) causing a lower MU signal-to-interference-plus-noise ratio (MU-SINR) and therefore a higher PER for a given modulation coding scheme (MCS).

With the introduction of up to eight (8) STAs in an MU-MIMO group for the Institute of Electrical and Electronics Engineers (IEEE) 802.11ax standard, where previous standards such as IEEE 802.11ac used up to four (4) STAs instead, the channel correlation impact becomes even more critical to MU-MIMO rate adaptation. The greater impact of channel correlation is because rate adaptation mechanisms are based solely on PER and the value of PER changes slowly as it is averaged over time, which in turn makes current rate adaptation mechanisms react very slowly to the effects of channel correlation.

There can be instances or scenarios in which a faster response to channel correlation for rate adaptation can improve MU-MIMO communications, particularly in WLANs. For example, with a larger number of STAs in an MU-MIMO PPDU (also referred simply as MU-PPDUs) because of the larger MU-MIMO group sizes allowed by the IEEE 802.11ax standard, the probability that some of the STAs run out of traffic, especially for transmission control protocol (TCP) traffic, grows higher. In such instances, the MU scheduler at the AP may need to reduce the number of STAs in subsequent MU-PPDUs. When the number of STAs in a subsequent MU-PPDU decreases, merely using the PER of a previous MU-PPDU to determine the MCS of the subsequent MU-PPDU can result in a sub-optimal MCS selection. Because the interference between STAs is likely to decrease when the number of STAs in a subsequent MU-PPDU decreases (e.g., there is less correlation between the STAs), the MU-SINR for each of the STAs in the subsequent MU-PPDU is likely to increase, or at least remain the same, compared to the MU-SINR of the previous MU-PPDU. This means that it is possible to increase the MCS for each of the STAs in the subsequent MU-PPDU as a result of these changes in channel correlation; however, current rate adaptation mechanisms could not react fast enough to enable such possible increase in MCS because they rely solely on slow-changing PER measurements.

Similar issues can also arise in other scenarios, such as when the MU-MIMO group size remains the same from one MU-PPDU to a subsequent MU-PPDU, but there is less channel correlation between STAs in the subsequent MU-PPDU. This can happen when a specific STA joins different MU-MIMO groups with different channel correlation statistics, for example, an STA A experiences low correlation when joining an MU-MIMO group of STAs {A, B, C}, but has higher correlation when joining MU-MIMO group with STAs {A, D, E}.

In these and similar scenarios, current rate adaptation mechanisms can also be limited because they are not able to account for the Doppler impact caused on the channel by movements in the AP and/or STA.

In view of the issues identified above, improvements to existing rate adaptation mechanisms are desirable to more effectively perform MU-MIMO communications in WLANs.

### SUMMARY

The present disclosure provides aspects related to techniques for MU-MIMO rate adaptation, and more specifically, to techniques for MU-MIMO rate adaptation in WLANs that employ joint or combined use of packet error metrics (e.g., PER) and signal quality metrics (e.g., MU-SINR). For example, a mechanism is described for MU-MIMO rate adaptation based jointly on PER and MU-SINR. Rate adaptation as described herein can refer to the selection of MCS, the selection of a number of spatial streams (Nss), or both. The MU-SINR can be calculated, estimated, or determined based on channel estimates reported by STAs as part of a channel sounding sequence through information in compressed beamforming (CBF) reports. The proposed mechanism provides for a more effective or accurate selection of MCS and/or Nss when, for example the MU-MIMO group size changes within a channel sounding interval. Changes in the MU-MIMO group size can occur when some STAs run out of traffic or have very little traffic. The proposed mechanism allows faster reaction to instantaneous (e.g., short term) channel correlation measurements compared to the existing rate adaptation schemes that rely solely on packet error metrics such as PER. The proposed mechanism addresses differences in rate adaptation when the MU-PPDU under consideration occurs immediately after the channel sounding sequence and when the MU-PPDU under consideration is a subsequent MU-PPDU that occurs within the channel sounding interval.

In one example, a method of MU-MIMO communications is disclosed. The method includes identifying, at an AP, a condition associated with the transmission of an MU-PPDU for multiple STAs. A packet error metric (e.g., PER) and a signal quality metric (e.g., MU-SINR) are determined for each of the STAs in response to the identification of the condition, and a rate is determined for each of the STAs based on the respective packet error metric and the respective signal quality metric. The MU-PPDU is then transmitted according to the respective rate for each of the STAs.

In another example, an apparatus for MU-MIMO communications is disclosed. The apparatus includes a memory that stores MU-MIMO communications instructions, and a processor coupled with the memory, and configured to execute the instructions to identify, at AP, a condition associated with the transmission of an MU-PPDU for multiple STAs. The processor is further configured to execute the instructions to determine a packet error metric (e.g., PER) and a signal quality metric (e.g., SINR) for each of the STAs in response to the identification of the condition and determine a rate for each of the STAs based on the respective packet error metric and the respective signal quality metric. The processor is also configured to execute the instructions to transmit the MU-PPDU according to the respective rate for each of the STAs.

In yet another example, an apparatus for MU-MIMO communications is disclosed. The apparatus includes means for identifying, at an AP, a condition associated with the transmission of an MU-PPDU for multiple STAs. The apparatus further includes means for determining a packet error metric (e.g., PER) and a signal quality metric (e.g., MU-SINR) for each of the STAs in response to the identification of the condition, and means for determining a rate for each of the STAs based on the respective packet error metric and the respective signal quality metric. The apparatus also includes means for transmitting the MU-PPDU according to the respective rate for each of the STAs.

In yet another example, a computer-readable medium storing executable code for MU-MIMO communications is disclosed. The code includes code for identifying, at an AP, a condition associated with the transmission of an MU-PPDU for multiple STAs. The code further includes code for determining a packet error metric (e.g., PER) and a signal quality metric (e.g., MU-SINR) for each of the STAs in response to the identification of the condition, and code for determining a rate for each of the STAs based on the respective packet error metric and the respective signal quality metric. The code also includes code for transmitting the MU-PPDU according to the respective rate for each of the STAs.

It is understood that other aspects of apparatuses and methods will become readily apparent to those skilled in the art from the following detailed description, wherein various aspects of apparatuses and methods are shown and described by way of illustration. As will be realized, these aspects may be implemented in other and different forms and its several details are capable of modification in various other respects. Accordingly, the drawings and detailed description are to be regarded as illustrative in nature and not as restrictive

### BRIEF DESCRIPTION OF THE DRAWINGS

FIG. 1 illustrates an example of a wireless communication system in which aspects of the present disclosure can be employed.

FIG. 2 illustrates an example of a first scenario or condition in which to use joint packet error and signal quality metrics for rate adaptation in connection with aspects of the present disclosure.

FIG. 3 illustrates an example of a second scenario or condition in which to use joint packet error and signal quality metrics for rate adaptation in connection with aspects of the present disclosure.

FIG. 4 illustrates an example of a third scenario or condition in which to use joint packet error and signal quality metrics for rate adaptation in connection with aspects of the present disclosure.

FIG. 5 illustrates an example of channel sounding in connection with aspects of the present disclosure.

FIG. 6 illustrates an example of rate adaptation immediately after a channel sounding sequence in connection with aspects of the present disclosure.

FIG. 7 illustrates another example of rate adaptation immediately after a channel sounding sequence in connection with aspects of the present disclosure.

FIG. 8 illustrates an example of hardware implementation of an AP that can be employed within a wireless communication system in accordance with various aspects of present disclosure.

FIG. 9 illustrates an example of hardware implementation of an STA that can be employed within a wireless communication system in accordance with various aspects of present disclosure.

FIG. 10 illustrates an example of a method for wireless communications implemented on an AP in accordance with various aspects of the present disclosure.

### DETAILED DESCRIPTION

Various concepts will be described more fully hereinafter with reference to the accompanying drawings. These concepts may, however, be embodied in many different forms by those skilled in the art and should not be construed as limited to any specific structure or function presented herein. Rather, these concepts are provided so that this disclosure will be thorough and complete, and will fully convey the scope of these concepts to those skilled in the art. The detailed description may include specific details. However, it will be apparent to those skilled in the art that these concepts may be practiced without these specific details.

As discussed above, current rate adaptation mechanisms are typically based on PER measurements made at the AP from information provided by STAs in the form of block acknowledgments (BAs) after the transmission of packets. Packet errors for MU-MIMO packets can happen because of different reasons, including collisions on the wireless medium, channel degradation from Doppler impact caused by AP and/or STA movement, and channel correlation among STAs in an MU-MIMO PPDU (MU-PPDU) causing a lower MU-SINK and therefore a higher PER for a given MCS.

With the introduction of the IEEE 802.11ax standard for WLAN communications, the maximum number of STAs in an MU-MIMO group is now eight (8) STAs instead of the four (4) STAs used in earlier standards such as IEEE 802.11ac, for example. Given the larger number of STAs, the channel correlation impact becomes even more critical to MU-MIMO rate adaptation at least for the reason that having more STAs for a PPDU can result in more interference among the STAs. Because current rate adaptation mechanisms are solely based on PER, and because the value of PER changes slowly as it is averaged over time based on the feedback provided to the AP by STAs, these rate adaptation mechanisms tend to react very slowly to the effects of channel correlation. This slow reaction may not allow the AP to determine an optimal rate and, consequently, the MCS and the Nss that are selected as part of the rate adaptation mechanism are likely to provide sub-optimal MU-MIMO communications between the AP and its associated STAs.

Additionally, with larger numbers of STAs in an MU-MIMO PPDU, the probability that some STAs run out of traffic, especially TCP traffic, is much higher. As a result, the MU scheduler at the AP may have to reduce the number of STAs in subsequent MU-PPDUs because of the lack of traffic available for transmission. Part of the reason for the reduction in the number of STAs is that MU-MIMO is more efficient when large amounts of traffic are transmitted to justify the overhead caused by the use of channel sounding. When the number of STAs in a subsequent MU-PPDU decreases, merely using the PER of a previous MU-PPDU to determine the MCS of the subsequent MU-PPDU would not be optimal. One reason is that as the number of STAs in a MU-PPDU decreases, the MU-SINR for each of the STAs is likely to increase, or at least remain the same, compared to the previous MU-PPDU because there is likely to be less inter-user (e.g., inter-STA) interference. This means that the MCS per STA in the subsequent MU-PPDU could potentially be increased. At the same time, the previous MU-PPDU might have experienced a high PER as a result of a Doppler impact on the channel or interference.

In view of these scenarios or conditions, the present disclosure proposes a solution in which both packet error metrics (e.g., PER) and signal quality metrics (e.g., MU-SINR) are used jointly during MU-MIMO rate adaptation mechanisms to make better selections of, for example, MCS and Nss, in subsequent MU-PPDUs at least in the types of scenarios or conditions described herein.

The proposed MU-MIMO rate adaptation mechanism can use the channel estimates provided in CBF reports to estimate the correlation among STAs. For example, an AP can estimate signal quality metrics (e.g., MU-SINR) for different STAs based on CBF reports. In one implementation, estimating channel correlation among STAs based on CBF reports can be done through the use of a Gram-Schmidt orthogonalization process, where the information resulting from this process can also be used in MU-MIMO grouping. Other implementations for estimating channel correlation among STAs can also be used in connection with the proposed MU-MIMO rate adaptation mechanism described herein.

In another aspect, the proposed MU-MIMO rate adaptation mechanism can have some differences depending on when does an MU-PPDU occur relative to the channel sounding interval. For example, the proposed MU-MIMO rate adaptation mechanism can be considered in two parts. A first part or first portion of the MU-MIMO rate adaptation mechanism involves the first MU-PPDU immediately after the channel sounding sequence is completed. A second part or second portion of the MU-MIMO rate adaptation mechanism involves any subsequent MU-PPDU within the channel sounding interval and after the first MU-PPDU. For example, the second, third, fourth, or any other MU-PPDU subsequent to the first MU-PPDU immediately after the channel sounding sequence is completed can be considered a subsequent MU-PPDU for purposes of the second part of the MU-MIMO rate adaptation mechanism.

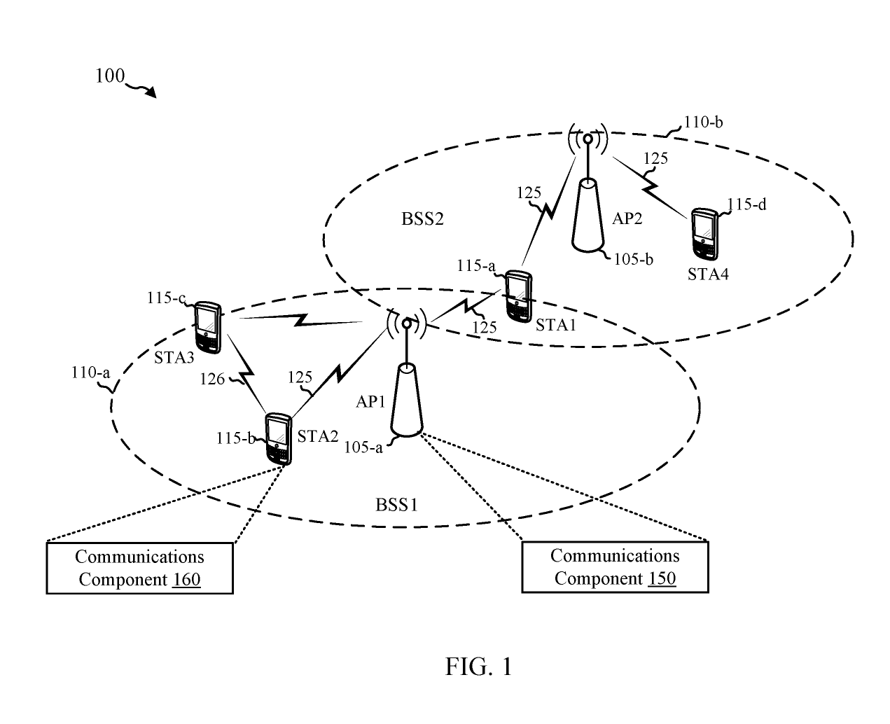

Additional details and explanations for the proposed MU-MIMO rate adaptation mechanism are provided below in connection with FIGS. 1-10.

FIG. 1 is a conceptual diagram 100 illustrating an example of a WLAN deployment in connection with various techniques described herein. The WLAN may include one or more APs and one or more wireless stations or STAs associated with a respective AP. In this example, there are two APs deployed: AP1 105-a in basic service set 1 (BSS1) and AP2 105-b in BSS2, which may be referred to as an overlapping BSS or OBSS. AP1 105-a is shown as having at least three associated STAs (STA1 115-a, STA2 115-b, and STA3 115-c) and coverage area 110-a, while AP2 105-b is shown having one associated STA4 115-d and coverage area 110-b. The STAs 115 and AP 105 associated with a particular BSS may be referred to as members of that BSS. In the example of FIG. 1, the coverage area of AP1 105-a can overlap part of the coverage area of AP2 105-b such that STA1 115-a can be within the overlapping portion of the coverage areas. The number of BSSs, APs, and STAs, and the coverage areas of the APs described in connection with the WLAN deployment of FIG. 1 are provided by way of illustration and not of limitation.

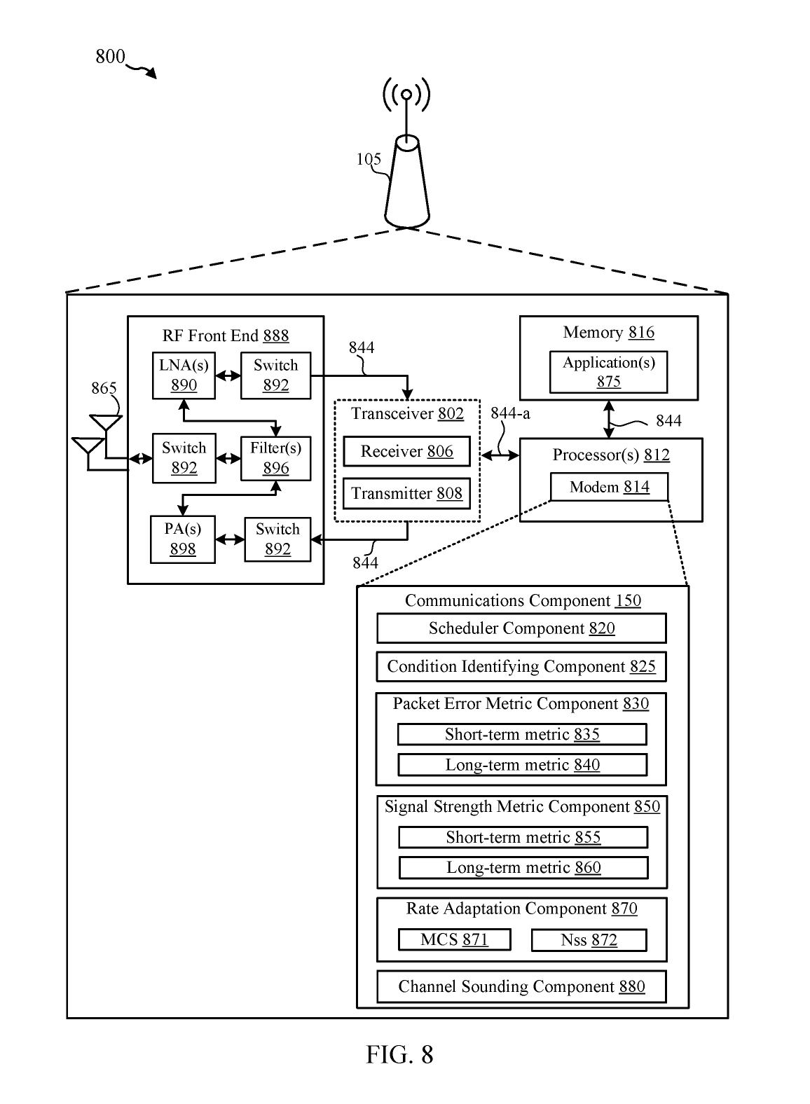

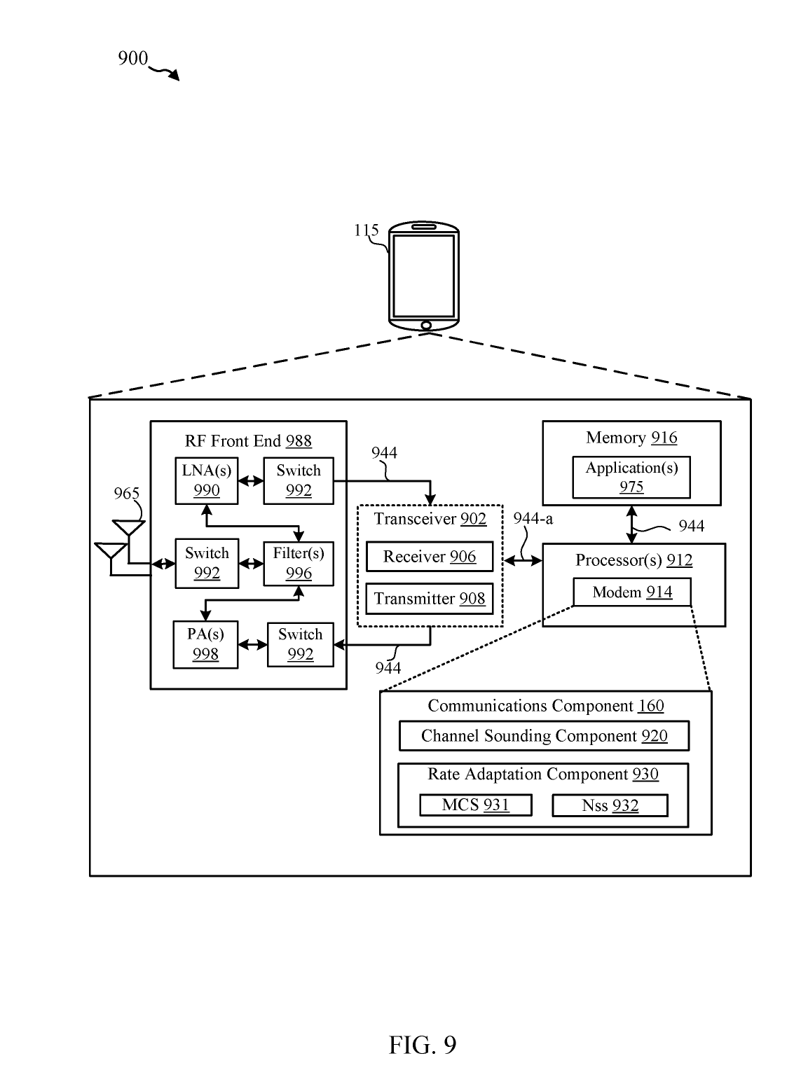

As described above, an AP, such as AP1 105-a or AP2 105-b can communicate with multiple STAs 115 using MU-MIMO communications techniques. When the IEEE 802.11ax standard is supported in such communications, an AP can have as many as eight (8) STAs join in an MU-PPDU. In the example shown in FIG. 1, AP1 105-a can have STA1 115-a, STA2 115-b, STA3 115-c, and up to five other STAs 115 in an MU-PPDU. To optimize MU-MIMO communications with multiple STAs, the AP1 105-a can include a communications component 150 (See e.g., FIG. 8) that is configured to perform aspects of the MU-MIMO rate adaptation mechanisms proposed in this disclosure. Similarly, an STA 115 communicating with the AP1 105-a, such as the STA2 115-b, for example, can include a communications component 160 (see e.g., FIG. 9) that is configured to provide information needed by the AP1 105-a (e.g., channel estimates in CBF reports) to perform aspects of the MU-MIMO rate adaptation mechanisms proposed in this disclosure.

In some examples, the APs (e.g., AP1 105-a and AP2 105-b) shown in FIG. 1 are generally fixed terminals that provide backhaul services to STAs 115 within its coverage area or region. In some applications, however, the AP may be a mobile or non-fixed terminal. The STAs (e.g., STA1 115-a, STA2 115-b, STA3 115-c, STA4 115-d) shown in FIG. 1, which can be fixed, non-fixed, or mobile terminals, utilize the backhaul services of their respective AP to connect to a network, such as the internet. Examples of an STA include, but are not limited to: a cellular phone, a smart phone, a laptop computer, a desktop computer, a personal digital assistant (PDA), a personal communication system (PCS) device, a personal information manager (PIM), personal navigation device (PND), a global positioning system, a multimedia device, a video device, an audio device, a device for the Internet-of-Things (IoT), a wearable device, or any other suitable wireless apparatus requiring the backhaul services of an AP. An STA may also be referred to by those skilled in the art as: a subscriber station, a mobile unit, a subscriber unit, a wireless unit, a remote unit, a mobile device, a wireless device, a wireless communications device, a remote device, a mobile subscriber station, an access terminal, a mobile terminal, a wireless station, a remote terminal, a handset, a user agent, a mobile client, a client, a user equipment (UE), a wearable device, or some other suitable terminology. An AP may also be referred to as: a base station, a base transceiver station, a radio base station, a radio transceiver, a transceiver function, a wireless or Wi-Fi hotspot, or any other suitable terminology. The various concepts described throughout this disclosure are intended to apply to all suitable wireless apparatus regardless of their specific nomenclature.

Each of STA1 115-a, STA2 115-b, STA3 115-c, and STA4 115-d can be implemented with a protocol stack. The protocol stack can include a physical layer for transmitting and receiving data in accordance with the physical and electrical specifications of the wireless channel, a data link layer for managing access to the wireless channel, a network layer for managing source to destination data transfer, a transport layer for managing transparent transfer of data between end users, and any other layers necessary or desirable for establishing or supporting a connection to a network.

Each of AP1 105-a and AP2 105-b can include software applications and/or circuitry to enable associated STAs to connect to a network via communications link 125. The APs can send frames or packets to their respective STAs and receive frames or packets from their respective STAs to communicate data and/or control information (e.g., signaling). As described above, communications between an AP and multiple STAs can include MU-MIMO communications, which include the transmission of MU-MIMO PPDUs (or referred simply as MU-PPDUs or PPDUs), and which can support WLAN standards such as the IEEE 802.11ax standard as well as other legacy standards (e.g., IEEE 802.11ac). As part of these MU-MIMO communications, an AP can perform the MU-MIMO rata adaptation mechanism proposed herein.

Each of AP1 105-a and AP2 105-b can establish a communications link 125 with an STA that is within the coverage area of the AP. Communications link 125 can comprise communications channels that can enable both uplink and downlink communications. When connecting to an AP, an STA can first authenticate itself with the AP and then associate itself with the AP. Once associated, a communications link 125 may be established between the AP 105 and the STA 115 such that the AP 105 and the associated STA 115 may exchange frames or messages through a direct communications link 125. It should be noted that the wireless communication system, in some examples, may not have a central AP (e.g., AP 105), but rather may function as a peer-to-peer network between the STAs (e.g., STA2 115-b and STA3 115-c over communication link 126). Accordingly, the functions of the AP 105 described herein may alternatively be performed by one or more of the STAs 115.

While aspects of the present disclosure are described in connection with a WLAN deployment or the use of IEEE 802.11-compliant networks, those skilled in the art will readily appreciate, the various aspects described throughout this disclosure may be extended to other networks employing various standards or protocols including, by way of example, BLUETOOTH® (Bluetooth), HiperLAN (a set of wireless standards, comparable to the IEEE 802.11 standards, used primarily in Europe), and other technologies used in wide area networks (WAN)s, WLANs, personal area networks (PAN)s, or other suitable networks now known or later developed. Thus, the various aspects presented throughout this disclosure for performing operations based on modifications and enhancements to MU-MIMO rate adaptation mechanisms can be applicable to any suitable wireless network regardless of the coverage range and the wireless access protocols utilized.

In some aspects, one or more APs (e.g., AP1 105-a and AP2 105-b) can transmit on one or more channels (e.g., multiple narrowband channels, each channel including a frequency bandwidth) a beacon signal (or simply a “beacon”), via a communications link 125 to STA(s) 115 of the wireless communication system, which can help the STA(s) 115 to synchronize their timing with the APs 105, or which may provide other information or functionality.

An AP (e.g., AP1 105-a) can perform an MU-MIMO rate adaptation mechanism based jointly on packet error metrics and signal quality metrics. A packet error metric can refer to a measurement, a value, an index, a parameter, or the like that indicates a degree of performance in the transmission of packets. An example of a packet error metric used by way of illustration in this disclosure is the PER. A signal quality metric can refer to a measurement, a value, an index, a parameter, or the like that indicates a degree of signal strength relative to noise and/or interference. An example of a signal quality metric used by way of illustration in this disclosure is the MU-SINR.

An AP (e.g., AP1 105-a or AP2 105-b) can use both PER and MU-SINR when performing MU-MIMO rate adaptation. Rate adaptation as described herein can refer to the selection of MCS, the selection of Nss, or both. MCS can be represented by an index value such that the selection of a desired MCS can be made by indicating the desired index value. In some instances, the selection of a desired MCS can be made by indicating the appropriate increase or decrease of the index value of a current MCS. The MU-SINR can be calculated, estimated, or determined based on channel estimates reported by STAs as part of a channel sounding sequence through information in CBF reports. By using both PER and MU-SINR, the AP can provide a more effective or accurate selection of MCS and/or Nss when, for example, the MU-MIMO group size changes within the sounding interval. Changes in the MU-MIMO group size can occur when some STAs run out of traffic or have very little traffic. By using both PER and MU-SINR in rate adaptation, the AP can react much faster to instantaneous (e.g., short term) channel correlation measurements compared to existing rate adaptation schemes that rely solely on packet error metrics such as PER. The AP can also address differences in rate adaptation when the MU-PPDU under consideration occurs immediately after the channel sounding sequence and when the MU-PPDU under consideration is a subsequent MU-PPDU that occurs within the channel sounding interval.

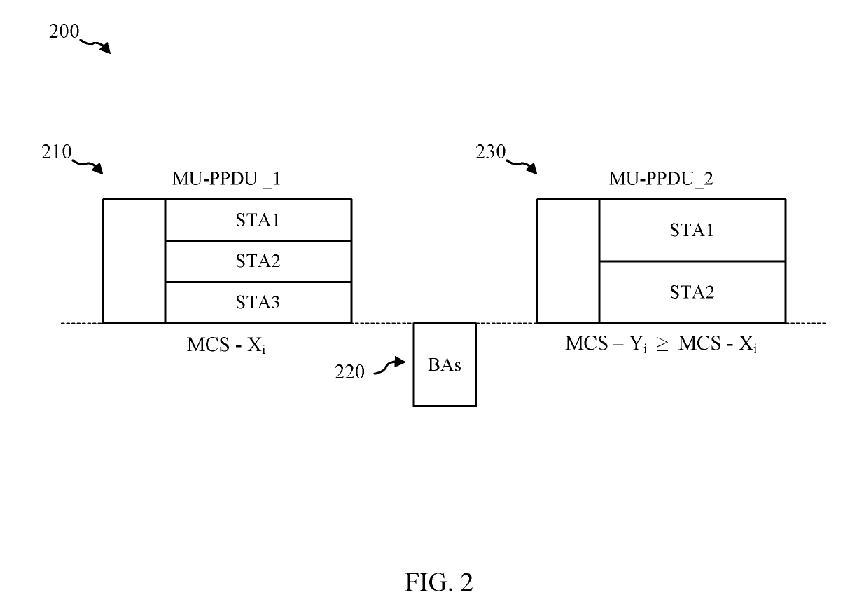

Additional details regarding several scenarios or conditions in which an AP can perform MU-MIMO rate adaptation by combining or jointly using packet error metrics and signal quality metrics are described below in connection with FIGS. 2-4.

FIG. 2 illustrates an example of a first scenario in which an AP can jointly use packet error and signal quality metrics for MU-MIMO rate adaptation. Timing diagram 200 shows a scenario or condition for a reduced number of users or STAs in which there are fewer number of STAs in a subsequent MU-PPDU (e.g., MU-PPDU_2 230) than in a previous MU-PPDU (e.g., MU-PPDU_1 210). As used herein, the terms MU-MIMO PPDU, MU-PPDU, or simply PPDU, can be used interchangeably.

As noted above, the IEEE 802.11ax standard supports a larger number of STAs in an MU-PPDU than previous standards and, consequently, the probability that at least some of those STAs run out of traffic grows higher, especially for TCP traffic. Because of the overhead caused by channel sounding, continuing an MU-PPDU burst with fewer STAs is more efficient than terminating the MU-PPDU burst whenever one or more STAs run out of traffic. By having a subsequent MU-PPDU with a smaller number of STAs, the MU-SINR for each of the STAs would likely increase compared to the previous MU-PPDU due to less inter-user interference. In such a scenario or condition, it is possible that the MCS for each of the STAs in the subsequent MU-PPDU can be increased, however, current rate adaptation mechanisms that merely depend on PER would not capture the possible MCS increase when there are fewer number of STAs, resulting in an overall performance loss. That is, the possibility of having a higher MU-SINR when the number of STAs decreases provides an opportunity to be more aggressive with the MCS selection.

Returning to the example in FIG. 2, an AP transmits the MU-PPDU_1 210 first, which includes three users or STAs (e.g., STA1, STA2, STA3). That is, MU-PPDU_1 210 uses an MU-MIMO group size of three (3) (e.g., MU-3). In response to the transmission of MU-PPDU_1 210, the respective STAs send block acknowledgments (BAs) 220 back to the AP. Information in the BAs 220 can be used by the AP to update or revise packet error metrics such as PER. For example, the information in the BAs 220 can indicate how many packets sent to the STAs were successfully received and/or how many failed to be properly received (e.g., packet error).

Based on available traffic for STA1, STA2, and STA3, the AP (e.g., an MU scheduler in the AP) determines that STA3 has ran out of traffic. Rather than terminate a current burst of MU-PPDUs as a result of STA3 running out of traffic, the AP subsequently transmits MU-PPDU_2 230 with only STA1 and STA2. That is, MU-PPDU_2 230 uses an MU-MIMO group size of two (2) (e.g., MU-2), which is smaller than the MU-MIMO group size of MU-PPDU_1 210. Because of the fewer STAs in MU-PPDU_1 210, there is likely to be less interference or channel correlation between the STAs, which can result in a higher MU-SINR, and consequently, a higher MCS for the STAs. This is illustrated in the expressions shown in FIG. 2, where MCS-Xᵢ represents the MCS for STA(i) in the previous MU-PPDU_1 210, MCS-Yᵢ represents the MCS for the same STA(i), in this case STA1 and STA2, in the subsequent MU-PPDU_2 230, and (i) indicates an index representative of a particular STA.

Additional details on the update or selection of MCS for the scenario or condition described in FIG. 2 are provided below. In general, channel correlation based on the processing of CBF reports provided as part of the channel sounding sequence can be used to estimate signal quality metrics such as MU-SINR. These estimates resulting from channel correlation can then be mapped to a change in MCS, such as ΔMCS_{c}, where the subscript c is indicative of a channel correlation-based ΔMCS.

In addition, the AP can track packet error metrics for every STA and every MU-MIMO group size separately. Accordingly, the AP can maintain long-term tables (e.g., long-term PER tables) for lower MU-MIMO group sizes, where the value for each of the STAs for each MU-MIMO group size is averaged over time and tracked in the respective table. The AP can make use of this information for updating a long-term packet error component of MCS, MCSₚ, where the subscript p is indicative of a packet error-based MCS.

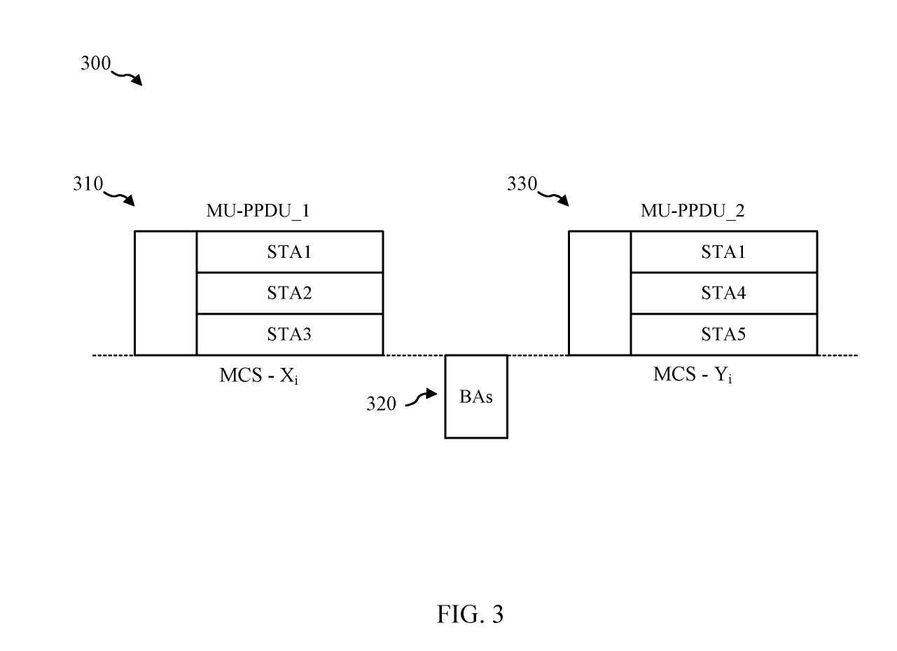

FIG. 3 illustrates an example of a second scenario in which an AP can jointly use packet error and signal quality metrics for MU-MIMO rate adaptation. Timing diagram 300 shows a scenario or condition for changing MU-MIMO groups of the same size within a channel sounding interval. In this scenario, a number of STAs in a subsequent MU-PPDU (e.g., MU-PPDU_2 330) is the same as a number of STAs in a previous MU-PPDU (e.g., MU-PPDU_1 310) but the STAs in the MU-PPDUs are different. That is, the MU-MIMO group in MU-PPDU_1 310 has different STAs than the MU-MIMO group in MU-PPDU_2 330 even though the two MU-MIMO groups are of the same size.

Because of channel correlation, lack of traffic in some STAs, or both, an AP (e.g., AP1 105-a or AP2 105-b) can end up changing MU-MIMO groups frequently, even within a channel sounding interval. In an example, a channel sounding interval can last 40 milliseconds and there could be approximately 20 MU-PPDUs of about 2 milliseconds transmitted within such a channel sounding interval. Therefore, there could be multiple instances within a channel sounding interval in which MU-MIMO groups change from one MU-PPDU to the next.

As a result of having different MU-MIMO groups in consecutive MU-MIMO PPDUs, the signal quality metric (e.g., MU-SINR) and hence the MCS for an STA joining multiple MU-MIMO groups can be different. For example, an STA that is common to two different MU-MIMO groups can have a better MU-SINR in a second MU-MIMO group than in a first MU-MIMO group as a result of less channel correlation between STAs in the second MU-MIMO group. Current MU-MIMO rate adaptation mechanisms may not be able to take advantage of potentially better signal quality metrics and MCS for a particular STA in the second MU-MIMO group because they generally rely solely on packet error metrics (e.g., PER) that are averaged across all MU-MIMO groups of the same size without distinguishing between different MU-MIMO groups of the same size that can be formed. That is, in this scenario, current MU-MIMO rate adaptation mechanisms would typically keep the MCS for an STA the same regardless of a change in MU-MIMO group.

Returning to the example in FIG. 3, an AP transmits the MU-PPDU_1 310 first, where MU-PPDU_1 310 uses a first MU-MIMO group that includes three users or STAs (e.g., STA1, STA2, STA3). That is, MU-PPDU_1 310 uses an MU-MIMO group size of three (3) (e.g., MU-3). In response to the transmission of MU-PPDU_1 310, the respective STAs send BAs 320 back to the AP. Information in the BAs 320 can be used by the AP to update or revise packet error metrics such as PER.

Based on available traffic and/or channel correlation for STA1, STA2, and STA3, the AP (e.g., an MU scheduler in the AP) determines to instead group STA1 with STA4 and STA5 in an MU-MIMO group to be used with a subsequent MU-PPDU (e.g., MU-PPDU_2 330). Rather than terminate a current burst of MU-PPDUs, the AP subsequently transmits MU-PPDU_2 330 with STA1, STA4, and STA5. That is, MU-PPDU_2 330 uses an MU-MIMO group size of three (3) (e.g., MU-3) just like MU-PPDU_1 310. The MCS for STA1 could change in MU-PPDU_2 330 if STA1 has less correlation with STA4 and STA5 than it did with STA2 and STA3 in MU-PPDU_1 310. This is illustrated in the expressions shown in FIG. 3, where MCS-Xᵢ represents the MCS for STA(i) in the previous MU-PPDU_1 310, MCS-Yᵢ represents the MCS for the same STA(i), in this case STA1, in the subsequent MU-PPDU_2 330, and (i) indicates an index representative of a particular STA.

Additional details on the update or selection of MCS for the scenario or condition described in FIG. 3 are provided below. In general, channel correlation based on the processing of CBF reports provided during channel sounding can be used to estimate signal quality metrics such as MU-SINR. These estimates resulting from channel correlation can then be mapped to a change in MCS, such as ΔMCS_{c}.

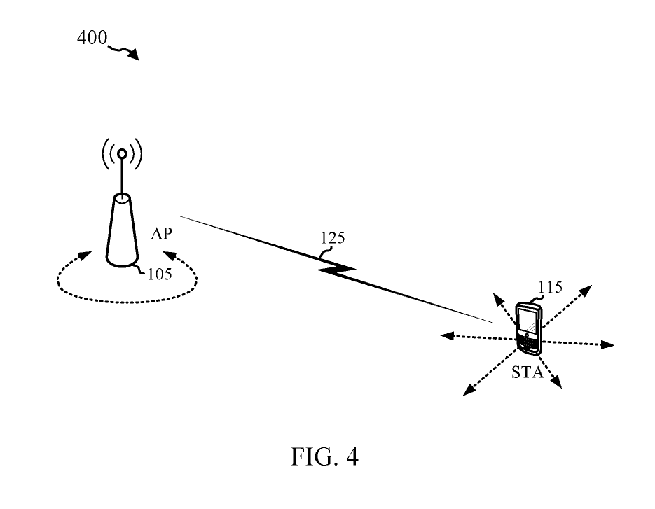

FIG. 4 illustrates an example of a third scenario in which an AP can use joint packet error and signal quality metrics for MU-MIMO rate adaptation. Conceptual diagram 400 shows a scenario or condition for MU-MIMO rate adaptation with joint consideration of reduced number of STAs (e.g., scenario or condition described in FIG. 2) or channel correlation (e.g., scenario or condition described in FIG. 3) with Doppler impact. In this scenario, because of movement (e.g., displacement, rotation) of an AP and/or STA(s), the channel can experience a Doppler impact, reducing the MCS for the STA(s). At the same time, one or more STAs can run out of traffic or the AP can change the MU-MIMO group. The Doppler impact can refer to the impact or effect on the channel characteristics by a Doppler shift caused by the movements described above.

Returning to FIG. 4, by way of illustration and not of limitation, an AP 105 is shown to rotate and cause a Doppler impact on the channel as a result. Similarly, an STA 115 is shown to displace in any one or more of different directions (e.g., by a user holding the STA 115 moving from one location to another), also causing a Doppler impact on the channel as a result. The channel in this instance can refer to a communication channel between the AP 105 and the STA 115. Communications link 125 can be part of the channel, can comprise the channel, or can be otherwise associated with the channel. The Doppler impact can result from the rotation of the AP 105, the displacement of the STA 115, or both. Although not shown in the example in FIG. 4, the AP 105 can also displace, the STA 115 can also rotate, such that the Doppler impact can result from the displacement of the AP 105, the rotation of the STA 115, or both. Moreover, the AP 105 can both displace and rotate, and so can the STA 115. In such a case, the Doppler effect can result from the overall movement of the AP 105, the overall movement of the STA 115, or both.

As discussed above, the Doppler impact can be an additional consideration when performing the proposed MU-MIMO rate adaptation mechanism in those scenarios where some STAs run out of traffic or the AP may change the MU-MIMO group. In both of these scenarios, it is possible to select a more aggressive or more conservative MCS than what would be selected by current MU-MIMO rate adaptation mechanisms. By taking into consideration the Doppler impact, the MCS selection can be further optimized.

Additional details on the update or selection of MCS for the scenario or condition described in FIG. 4 are provided below. In general, channel correlation based on the processing of CBF reports provided during channel sounding can be used to estimate signal quality metrics such as MU-SINR. These estimates resulting from channel correlation can then be mapped to a change in MCS, such as ΔMCS_{c}.

In addition, the AP can track packet error metrics for every STA and every MU-MIMO group size separately. Accordingly, the AP can maintain long-term tables (e.g., long-term PER tables) for lower MU-MIMO group sizes, where the value for each of the STAs for each MU-MIMO group size is averaged over time and tracked in the respective table. The AP can make use of this information for updating a packet error long-term component of MCS, MCSₚ.

Moreover, the AP can determine short-term packet error metrics (e.g., short-term PER) based on the information provided in BAs from a previous MU-PPDU to capture the Doppler impact. The short-term packet error metric can be mapped to a change in MCS, such as ΔMCSₚ.

In this disclosure, short-term metrics can refer to short-term or instantaneous packet error metrics. For example, short-term/instantaneous packet error metrics can include short-term PER obtained from information provided in BAs from an immediately previous MU-PPDU. Short-term metrics can also refer to short-term or instantaneous signal quality metrics. For example, short-term/instantaneous signal quality metrics can include MU-SINR estimated from channel information provided in CBF reports.

In this disclosure, long-term metrics can refer to long-term packet error metrics, such as long-term PER metrics. An AP can maintain long-term PER metrics in tables, where the long-term PER metrics include PER averages for each of the STAs for each MU-MIMO group size. Long-term metrics can also refer to long-term signal quality metrics, such as historic MU-SINR.

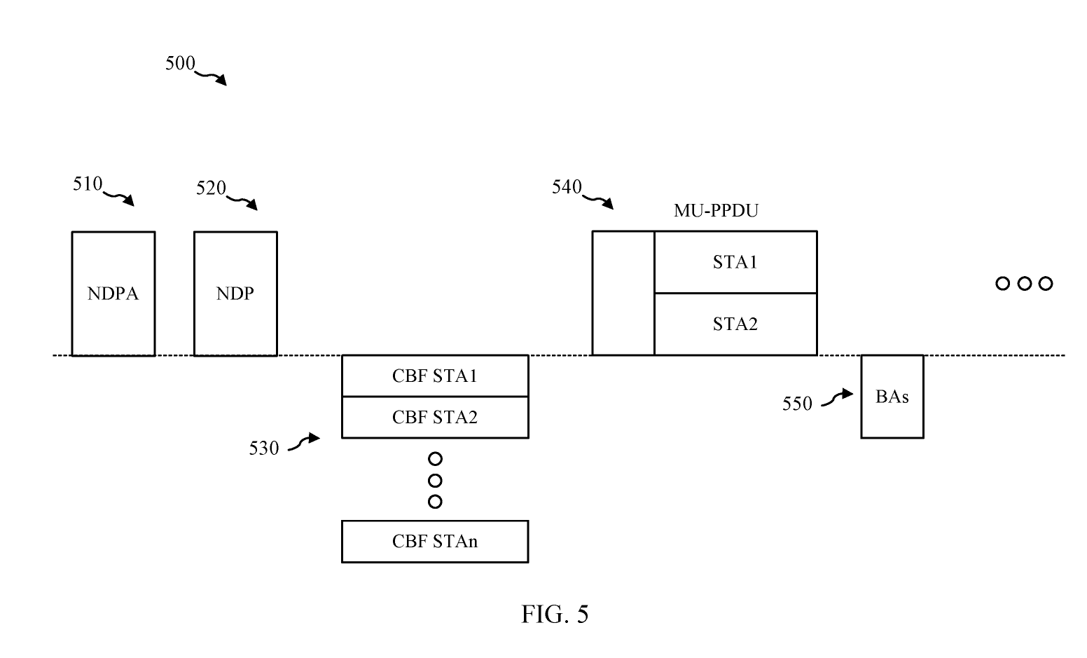

The scenarios described with respect to FIGS. 2, 3, and 4 above take place in connection with a channel sounding interval in which an AP performs a channel sounding sequence that is repeated at the next interval. FIG. 5 illustrates an example of channel sounding operation in connection with the MU-MIMO rate adaptation scenarios described above.

In FIG. 5 there is shown a timing diagram 500 in which an AP (e.g., AP1 105-a or AP2 105-b in FIG. 1) initiates a channel sounding sequence that is part of a current channel sounding interval. Channel sounding is typically used by the AP to evaluate characteristics of the channel for wireless communications. For example, channel sounding can be used to determine how to radiate energy in a preferred direction (e.g., beamforming) for MU-MIMO communications based on certain channel calibration procedures.

During the channel sounding sequence, the AP (e.g., the beamformer) transmits a null data packet announcement (NDPA) 510, which is used to gain control of the channel and identify STAs that will receive the beamformed transmissions from the AP (e.g., the beamformees). The AP follows the NDPA 510 with the transmission of an NDP 520, which is used by the receiving STA to analyze training fields to calculate the channel response. Typically, one NDP 520 is transmitted for single user (SU) and MU applications.

In response to the NDP(s) 520, the STAs send back to the AP CBF reports 530. In this example, STA1, STA2, STA3, . . . , STAn send back a CBF report 530 to the AP. STA1 sends back CBF STA1, STA2 sends back CBF STA2, and so on. The CBF report 530 can include channel information obtained from analyzing the training fields or other information provided in the NDP(s) 520. In an example, the channel information can be in the form of a feedback matrix, which the AP can use to generate a steering matrix.

With the information provided in the CBF reports 530, the AP can schedule MU-MIMO transmissions and perform aspects of the proposed MU-MIMO rate adaptation mechanism described herein. For example, as shown in FIG. 5, the AP can schedule the transmission of a first MU-PPDU 540 after the channel sounding sequence (e.g., NDPA 510, NDP(s) 520, and CBF reports 530). Any MU-PPDU transmitted after MU-PPDU 540 can be referred to as a subsequent MU-PPDU within the channel sounding interval.

After transmitting MU-PPDU 540 with the MU-MIMO group including STA1 and STA2, the AP can receive BAs 550 from STA1 and STA2. As described above, the BAs 550 can be used by the AP to obtain short-term packet error metrics, such as short-term PER. Because MU-PPDU 540 does not have the benefit of any BAs prior to its transmission, since it is the first MU-PPDU transmitted in the current channel sounding interval, MU-MIMO rate adaptation for MU-PPDU 540 can be somewhat different from MU-MIMO rate adaptation for any subsequent MU-PPDU in the current channel sounding interval. Accordingly, the proposed MU-MIMO rate adaptation mechanism described herein includes a first portion or part for the first MU-PPDU after completion of the channel sounding sequence, and a second portion or part for any MU-PPDU that occurs subsequent to the first MU-PPDU. Additional details in this regard are provided below.

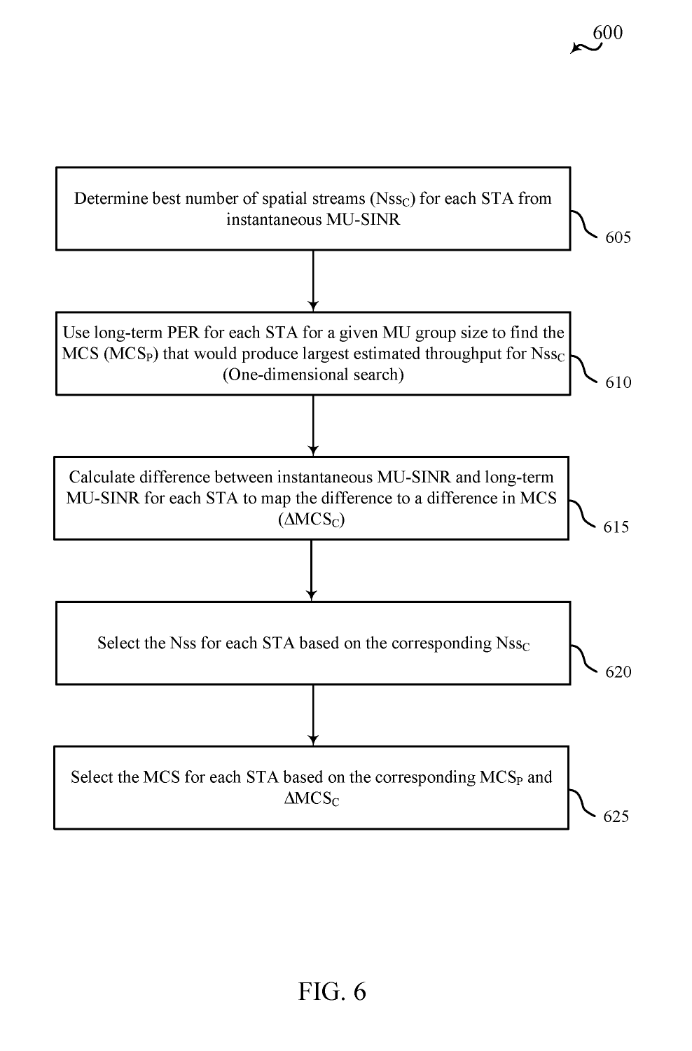

FIG. 6 illustrates an example of rate adaptation immediately after the channel sounding sequence is completed. More specifically, a method 600 in FIG. 6 describes various aspects of a first approach for the first part of the proposed MU-MIMO rate adaptation mechanism in which the rate (e.g., MCS and/or Nss) is adapted for the first MU-PPDU after the channel sounding sequence is completed. An example of a first MU-PPDU is MU-PPDU 540 in FIG. 5.

Operations associated with the method 600 can be performed by an AP, such as the AP 105 in FIG. 8, and more specifically, by a rate adaptation component such as the rate adaptation component 870 of the AP 105 in FIG. 8. For example, calculations, determinations, estimations, and/or selections associated with MCS can be performed by MCS 871 of the rate adaptation component 870. Similarly, calculations, determinations, estimations, and/or selections associated with Nss can be performed by Nss 872 of the rate adaptation component 870.

At 605, CBF reports (e.g., CBF reports 530 in FIG. 5) can be used to measure an instantaneous (e.g., short-term) MU-SINR and determine the best number of spatial streams for each of the STAs, Nss_{c}⁽ⁱ⁾, where (i) indicates an index representative of a particular STA and the subscript c is indicative of channel correlation-based Nss. For example, an AP can determine whether to use 1 or 2 spatial streams for a particular STA in an MU-MIMO group.

At 610, long-term PER can be used for each STA(i) and for a given MU-MIMO group size to find or determine the MCS that would provide the largest estimated throughput (e.g., goodput) for Nss_{c}⁽ⁱ⁾. The estimated throughput or goodput is obtained based on the following equation:

Goodput=PHY-rate×(1−PER⁽ⁱ⁾), (1)

where there is a PHY-rate associated with each MCS-Nss pair, and where PER⁽ⁱ⁾ corresponds to the long-term PER for STA(i). Equation (1) can then be used to obtain the MCS that maximizes throughput for an STA(i) given Nss_{c}⁽ⁱ⁾, MCSₚ⁽ⁱ⁾ where the subscript p is indicative of a packet error-based MCS.

The approach described in 610 can be referred to as a one-dimensional search because the Nss_{c}⁽ⁱ⁾ is known from 605 and there is a single rate adaptation component being searched using long-term PER tables in 610, MCSₚ⁽ⁱ⁾.

At 615, a difference between an instantaneous (e.g., short-term) MU-SINR and a historic (e.g., long-term) MU-SINR can be calculated for each STA(i), and this difference (e.g., ΔMU-SINR⁽ⁱ⁾) can then be mapped to a difference in MCS, ΔMCS_{c}⁽ⁱ⁾. In an example, the historic MU-SINR can be 30 dB and the instantaneous MU-SINR can be 33 dB, and the 3 dB difference can be mapped to an increase by 1 in the MCS index value (e.g., MCS+1).

The ΔMU-SINK⁽ⁱ⁾ to ΔMCS_{c}⁽ⁱ⁾ mapping can be obtained as an initial table based on the difference (Δ) of the required minimum MU-SINR to decode consecutive MCSs. The table can be adapted in real-time to account for channel variations.

The historic MU-SINR can be used to update the long-term PER tables that may not be up-to-date. For example, if the historic MU-SINR for a particular user or STA is high (e.g., 30 dB), the AP through a rate adaptation component (e.g., the rate adaptation component 870) can update the long-term PER tables to reflect that for low MCSs (e.g., 0-5) the PER values are to be small or zero.

At 620, the Nss for STA(i) at time t can be selected based on the following equation:

Nss⁽ⁱ⁾(t)=Nss_{c}⁽ⁱ⁾. (2)

At 625, the MCS for STA(i) at time t can be selected based on the following equation:

MCS⁽ⁱ⁾(t)=round(MCSₚ⁽ⁱ⁾+β·ΔMCS_{c}⁽ⁱ⁾), (3)

where 0≤β≤1 is a weighting factor for the change in MCS due to MU-SINR. In equation (3), the component MCSₚ⁽ⁱ⁾ represents the contribution of long-term PER (e.g., long-term packet error metric) in the selection of MCS, while the component ΔMCS_{c}⁽ⁱ⁾ represents the contribution of channel correlation due to using a different MU-MIMO group size (e.g., scenario in FIG. 2) or due to using a different MU-MIMO group (e.g., scenario in FIG. 3). The weighting factor or parameter β controls how aggressive the AP takes into account the component ΔMCS_{c}⁽ⁱ⁾ in equation (3). A high value of β gives more confidence to the contribution of channel correlation to MCS, while a low value of β gives more confidence to the contribution of long-term PER to MCS.

Although the example of method 600 is described in connection with PER and MU-SINR as metrics, a similar approach can be followed when other packet error metrics and signal quality metrics are used instead.

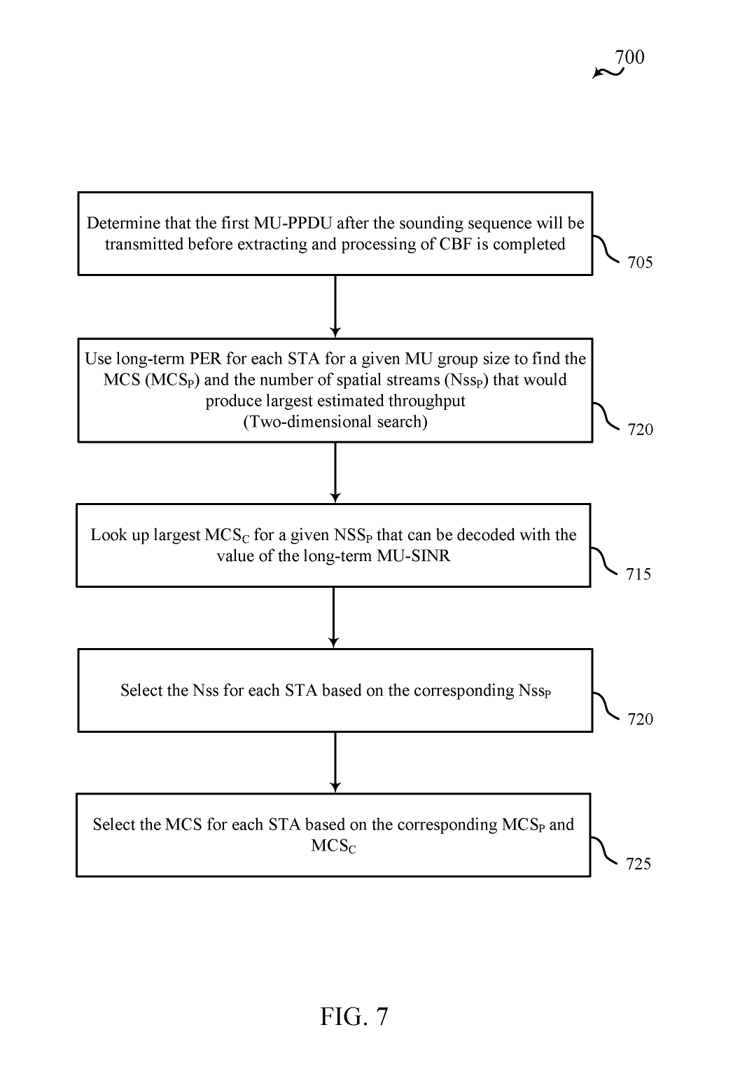

FIG. 7 illustrates another example of rate adaptation immediately after channel sounding in connection with aspects of the present disclosure. More specifically, method 700 in FIG. 7 describes various aspects of a second approach for the first part of the proposed MU-MIMO rate adaptation mechanism in which the rate (e.g., MCS and/or Nss) is adapted for the first MU-PPDU after the channel sounding sequence is completed. An example of a first MU-PPDU is MU-PPDU 540 in FIG. 5.

Operations associated with the method 700 can be performed by an AP, such as the AP 105 in FIG. 8, and more specifically, by a rate adaptation component such as the rate adaptation component 870 of the AP 105 in FIG. 8. For example, calculations, determinations, estimations, and/or selections associated with MCS can be performed by MCS 871 of the rate adaptation component 870. Similarly, calculations, determinations, estimations, and/or selections associated with Nss can be performed by Nss 872 of the rate adaptation component 870.

At 705, the AP can determine that extracting and processing the CBF reports (e.g., CBF reports 530 in FIG. 5) may take more than the time needed to send an MU-PPDU after the sounding sequence is completed. That is, the AP can determine that it may not be able to calculate or determine the instantaneous MU-SINR before sending the first MU-PPDU. Accordingly, the AP is not able to use the instantaneous MU-SINR to determine the Nss for each STA(i) at this stage.

At 710, long-term PER can be used for each STA(i) and for a given MU-MIMO group size to find or determine the MCS and Nss that would provide the largest estimated throughput (e.g., goodput). The estimated throughput or goodput is obtained based on equation (1) described above. Equation (1) can then be used to obtain the MCS and Nss that maximize throughput for an STA(i), MCSₚ⁽ⁱ⁾ and Nssₚ⁽ⁱ⁾.

The approach described in 710 can be referred to as a two-dimensional search because there are two rate adaptation components being searched using long-term PER tables in 710, MCSₚ⁽ⁱ⁾ and Nssₚ⁽ⁱ⁾.

At 715, the AP looks up or identifies the largest MCS_{c}⁽ⁱ⁾ for a given Nssₚ⁽ⁱ⁾ that can be decoded with the historic (e.g., long-term) MU-SINR value for each STA(i) in a given MU-MIMO group size.

The MU-SINR to MCS/Nss mapping can be obtained as an initial table based on a minimum MU-SINR needed to decode a specific MCS. The table can be adapted in real-time to account for channel variations.

At 720, the Nss for STA(i) at time t can be selected based on the following equation:

Nss⁽ⁱ⁾(t)=Nssₚ⁽ⁱ⁾. (4)

At 725, the MCS for STA(i) at time t can be selected based on the following equation:

MCS⁽ⁱ⁾(t)=round((1−β)·MCSₚ⁽ⁱ⁾+β·MCS_{c}⁽ⁱ⁾), (5)

where 0≤β≤1 is a weighting factor for the change in MCS due to historic MU-SINR. In equation (5), the component MCSₚ⁽ⁱ⁾ represents the contribution of long-term PER (e.g., long-term packet error metric) in the selection of MCS, while the component MCS_{c}⁽ⁱ⁾ represents the contribution of channel correlation due to using a different MU-MIMO group size (e.g., scenario or condition in FIG. 2) or due to using a different MU-MIMO group (e.g., scenario or condition in FIG. 3). The weighting factor or parameter β controls how aggressive the AP takes into account the component MCS_{c}⁽ⁱ⁾ in equation (5). A high value of β gives more confidence to the contribution of channel correlation to MCS, while a low value of β gives more confidence to the contribution of long-term PER to MCS.

Alternatively, the MCS for STA(i) at time t can be selected at 725 based on the following equation:

MCS⁽ⁱ⁾(t)=MCS_{c}⁽ⁱ⁾+ΔMCS, (6)

where ΔMCS is a margin depending on whether the AP is to be aggressive or conservative in MCS selection, e.g. −1, 0, +1.

Although the example of method 700 is described in connection with PER and MU-SINR as metrics, a similar approach can be follow when other packet error metrics and signal quality metrics are used instead.

As described above, methods 600 and 700 describe two different approaches for the first part of the proposed MU-MIMO rate adaptation mechanism in which the rate (e.g., MCS and/or Nss) is adapted for the first MU-PPDU after the channel sounding sequence is completed. For subsequent MU-PPDUs in the channel sounding interval, for example, those MU-PPDU occurring after the MU-PPDU 540 in FIG. 5, a second part of the proposed MU-MIMO rate adaptation can be used in view of the availability of short-term packet error metrics (e.g., short-term PER) that can be obtained from the BAs 550.

Based on PER of the previous MU-PPDU (e.g., instantaneous or short-term PER), an AP can calculate ΔMCSₚ for a subsequent MU-PPDU in the channel sounding interval, where ΔMCSₚ is a rate drop down (e.g., a drop in MCS) due to PER of the previous MU-PPDU. This drop in MCS can account for using a less than optimal MCS in the previous MU-PPDU or for a Doppler impact on the channel.

Below is an example of various thresholds that can be used to implement the drop in MCS:

If 0<PER<threshold 1(th1),then ΔMCSₚ=0;

Else if th1≤PER<threshold 2(th2),then ΔMCSₚ=−v1;

Else if th2≤PER<threshold 3(th3),then ΔMCSₚ=−v2;

Else if PER≥threshold 3(th3),then ΔMCSₚ=−v3,

where PER again refers to the instantaneous or short-term PER that can be calculated or obtained by a subsequent MU-PPDU from feedback provided in response to the previous MU-PPDU, where ΔMCSₚ=0 indicates that no Doppler impact compensation is needed in MCS, and where −v1 corresponds to a first drop in MCS, −v2 corresponds to a larger drop in MCS compared to −v1, and −v3 corresponds to a larger drop in MCS compared to −v2.

In an implementation, th1=5%, th2=15%, th3=25%, −v1 corresponds to a drop of 1 in the MCS index value (MCS-1), −v2 corresponds to a drop of 2 in the MCS index value (MCS-2), and −v3 corresponds to a drop of 3 in the MCS index value (MCS-3). It would be apparent to a person of skill in the art that other implementation using a different set of thresholds and MCS drops can also be used in connection with this aspect of the proposed MU-MIMO rate adaptation.

Further to the second part of the MU-MIMO rate adaptation, based on MU-SINR estimates obtained from information in the received CBF reports (e.g., CBF reports 530 in FIG. 5), an AP can calculate or determine the MU-SINR for each STA(i).

The AP can then calculate the difference between the instantaneous (e.g., short-term) MU-SINR for the MU-MIMO group size that will be used in the next MU-PPDU transmission and the historic (e.g., long-term) MU-SINR for each STA(i), and map this difference to a difference in MCS, ΔMCS_{c}⁽ⁱ⁾.

Therefore, for subsequent MU-PPDUs within the channel sounding interval, the Nss for STA(i) at time t can be selected based on the following equation:

Nss⁽ⁱ⁾(t)=Nss⁽ⁱ⁾(t−1). (7)

For subsequent MU-PPDUs within the channel sounding interval, the MCS for STA(i) at time t can be selected based on the following equation:

MCS⁽ⁱ⁾(t)=MCSₚ⁽ⁱ⁾+round(α·ΔMCSₚ⁽ⁱ⁾+β·βMCS_{c}⁽ⁱ⁾), (8)

where MCSₚ⁽ⁱ⁾=MCS⁽ⁱ⁾ (t) (the MCS of STA(i) in the previous MU-PPDU) when there is no MU-MIMO group size change between t and t−1, where MCSₚ⁽ⁱ⁾=MCS_{Gt}⁽ⁱ⁾ (Gt being the MU-MIMO group size at time t) when the MU-MIMO group size at time t changes to Gt and MCS_{Gt}⁽ⁱ⁾ corresponds to the long-term PER for STA(i) for MU-MIMO group size Gt, and where 0≤α, β≤1 are weighting factors for the change in MCS due to PER (α) and MU-SINR(β).

Although the example of the second part of the proposed MU-MIMO rate adaptation mechanism is described in connection with PER and MU-SINR as metrics, a similar approach can be follow when other packet error metrics and signal quality metrics are used instead.

FIG. 8 illustrates an example of hardware implementation of an AP 105 (e.g., AP1 105-a or AP2 105-b in FIG. 1) that can be employed within a wireless communication system to perform the proposed MU-MIMO rate adaptation mechanism described in connection with the scenarios or conditions discussed above. The hardware components and subcomponents of the AP 105 can be used to implement one or more methods (e.g., methods 600, 700, and 1000) described herein, including various aspects associated with the first and second parts of the proposed MU-MIMO rate adaptation mechanism. For example, one example of an implementation of AP 105 can include a variety of components, some of which have already been described above, but including components such as one or more processors 812, memory 816, and transceiver 802 in communication via one or more buses 844, which may operate in conjunction with the communications component 150 to enable one or more of the functions described herein related to including one or more methods of the present disclosure. Further, the one or more processors 812, which include a modem 814, memory 816, transceiver 802, RF front end 888 and one or more antennas 865, may be configured to support voice and/or data calls (simultaneously or non-simultaneously) in one or more radio access technologies (RATs).

In an aspect, the one or more processors 812 can include the modem 814 that uses one or more modem processors. The various functions related to the communications component 150 can be included in modem 814 and/or processors 812 and, in an aspect, can be executed by a single processor, while in other aspects, different ones of the functions may be executed by a combination of two or more different processors. For example, in an aspect, the one or more processors 812 can include any one or any combination of a modem processor, or a baseband processor, or a digital signal processor, or a transmit processor, or a receiver processor, or a transceiver processor associated with transceiver 802. In other aspects, some of the features of the one or more processors 812 and/or modem 814 associated with the communications component 150 can be performed by transceiver 802.

Also, memory 816 can be configured to store data and/or instructions used herein, local versions of applications 875, and/or local versions of the communications component 150, including one or more of its subcomponents being executed by at least one processor 812. Memory 816 can include any type of computer-readable medium usable by a computer or at least one processor 812, such as random access memory (RAM), read only memory (ROM), tapes, magnetic discs, optical discs, volatile memory, non-volatile memory, and any combination thereof. In an aspect, for example, memory 816 may be a non-transitory computer-readable storage medium that stores one or more computer-executable codes defining the communications component 150 and/or one or more of its subcomponents, and/or data associated therewith, when AP 105 is operating at least one processor 812 to execute the communications component 150 and/or one or more of its subcomponents.

Transceiver 802 can include at least one receiver 806 and at least one transmitter 808. Receiver 806 can include hardware, firmware, and/or software code executable by a processor for receiving data, the code comprising instructions and being stored in a memory (e.g., computer-readable medium). Receiver 806 can be, for example, a radio frequency (RF) receiver. In an aspect, receiver 806 can receive signals transmitted by at least one STA 115. Additionally, receiver 806 can process such received signals, and also may obtain measurements of the signals, such as, but not limited to, Ec/To, SNR, SINR, RSRP, RSSI, etc. Transmitter 808 can include hardware, firmware, and/or software code executable by a processor for transmitting data, the code comprising instructions and being stored in a memory (e.g., computer-readable medium). A suitable example of transceiver 802 can include, but is not limited to, an RF transmitter.

Moreover, in an aspect, AP 105 can include RF front end 888, which can operate in communication with one or more antennas 865 and transceiver 802 for receiving and transmitting radio transmissions, for example, wireless communications transmitted by at least one STA 115 or wireless transmissions transmitted by AP 105. RF front end 888 can be connected to one or more antennas 865 and can include one or more low-noise amplifiers (LNAs) 890, one or more switches 892, one or more power amplifiers (PAs) 898, and one or more filters 896 for transmitting and receiving RF signals.

In an aspect, LNA 890 can amplify a received signal at a desired output level. In an aspect, each LNA 890 can have a specified minimum and maximum gain values. In an aspect, RF front end 888 can use one or more switches 892 to select a particular LNA 890 and its specified gain value based on a desired gain value for a particular application.

Further, for example, one or more PA(s) 898 can be used by RF front end 888 to amplify a signal for an RF output at a desired output power level. In an aspect, each PA 898 can have specified minimum and maximum gain values. In an aspect, RF front end 888 can use one or more switches 892 to select a particular PA 898 and its specified gain value based on a desired gain value for a particular application.

Also, for example, one or more filters 896 can be used by RF front end 888 to filter a received signal to obtain an input RF signal. Similarly, in an aspect, for example, a respective filter 896 can be used to filter an output from a respective PA 898 to produce an output signal for transmission. In an aspect, each filter 896 can be connected to a specific LNA 890 and/or PA 898. In an aspect, RF front end 888 can use one or more switches 892 to select a transmit or receive path using a specified filter 896, LNA 890, and/or PA 898, based on a configuration as specified by transceiver 802 and/or processor 812.

As such, transceiver 802 can be configured to transmit and receive wireless signals through one or more antennas 865 via RF front end 888. In an aspect, transceiver 802 can be tuned to operate at specified frequencies such that AP 105 can communicate with, for example, one or more STAs 115 or one or more cells associated with one or more APs 105. In an aspect, for example, modem 814 can configure transceiver 802 to operate at a specified frequency and power level based on the AP configuration of the AP 105 and the communication protocol used by modem 814.

In an aspect, modem 814 can be a multiband-multimode modem, which can process digital data and communicate with transceiver 802 such that the digital data is sent and received using transceiver 802. In an aspect, modem 814 can be multiband and be configured to support multiple frequency bands for a specific communications protocol. In an aspect, modem 814 can be multimode and be configured to support multiple operating networks and communications protocols. In an aspect, modem 814 can control one or more components of AP 105 (e.g., RF front end 888, transceiver 802) to enable transmission and/or reception of signals from the network based on a specified modem configuration. In an aspect, the modem configuration can be based on the mode of the modem 814 and the frequency band in use. In another aspect, the modem configuration can be based on AP configuration information associated with AP 105 as provided by the network during cell selection and/or cell reselection.

In some examples, the communications component 150 can include a scheduler component 820, a condition identifying component 825, a packet error metric component 830, a signal quality metric component 850, the rate adaptation component 870, and a channel sounding component 880.

The channel sounding component 880 can be configured to perform channel sounding based on a channel sounding interval (e.g., 40 milliseconds) and using a channel sounding sequence as illustrated in FIG. 5. The channel sounding component 880 can be configured to generate the appropriate packets (e.g., NDPA 510, NDP(s) 520) and process the information received (e.g., CBF reports 530).

The scheduler component 820 can be configured to schedule MU-PPDU transmissions, including the first MU-PPDU after the channel sounding sequence is completed and any subsequent MU-PPDUs. The scheduler component 820 can schedule the MU-MIMO group and group size for a particular MU-MIMO PPDU to be transmitted. The scheduler component 820 can take into consideration the availability of traffic for a particular STA when determining the MU-MIMO group and group size to use for an MU-MIMO PPDU. The scheduler component 820 can also be referred to as an MU scheduler or an MU-MIMO scheduler.

The condition identifying component 825 can be configured to identify scenarios or conditions when the MU-MIMO rate adaptation mechanism performed by the AP 105 can jointly use packet error metrics (e.g., PER) and signal quality metrics (e.g., MU-SINR). For example, the condition identifying component 825 can identify a first condition in which the MU-MIMO group size is smaller in a subsequent MU-PPDU compared to a previous MU-PPDU (e.g., scenario or condition described above with respect to FIG. 2). The condition identifying component 825 can also identify a second condition in which the MU-MIMO group changes in a subsequent MU-PPDU compared to a previous MU-PPDU. The condition identifying component 825 can also identify a third condition in which the first condition or the second condition occurs along with a Doppler impact on the communications channel. This third condition can refer to a joint consideration of a reduced number of STAs (first condition) or channel correlation (second condition), and the Doppler impact. The condition identifying component 825 can rely on information provided by at least the channel sounding component 880 or the scheduler component 820 to identify any one of the scenarios or conditions described above. Moreover, the condition identifying component 825 can be configured to identify whether to implement the first part or the second part of the proposed MU-MIMO rate adaptation mechanism for a particular MU-PPDU transmission, although this function can be shared or performed by the rate adaptation component 870.

The packet error component 830 can be configured to determine, calculate, estimate, identify, and/or store short-term packet error metrics (e.g., short-term metric 835) and long-term packet error metrics (e.g., long-term metric 840). The short-term metric 835 can include instantaneous or short-term PER, while the long-term metric 840 can include long-term PER. In an aspect, the packet error component 830 can be configured to maintain tables having long-term PER information for different STAs in connection with the long-term metric 840.

The signal strength component 850 can be configured to determine, calculate, estimate, identify, and/or store short-term signal quality metrics (e.g., short-term metric 855) and long-term signal quality metrics (e.g., long-term metric 860). The short-term metric 855 can include instantaneous or short-term MU-SINR, while the long-term metric 860 can include long-term or historic MU-SINR. In an aspect, the signal strength component 830 can be configured to estimate MU-SINR for different STAs in connection with the short-term metric 855.

The rate adaptation component 870 is configured to perform various aspects of the MU-MIMO rate adaptation mechanism proposed in the present disclosure. The rate adaptation component 870 is configured to perform the first part of the MU-MIMO rate adaptation mechanism for those MU-PPDUs that are the first MU-PPDU transmitted after completion of the channel sounding sequence. In this regard, the rate adaptation component 870 can implement a first approach for the first part of the MU-MIMO rate adaptation mechanism (see e.g., method 600 in FIG. 6) or a second approach for the first part of the MU-MIMO rate adaptation mechanism (see e.g., method 700 in FIG. 7).

The rate adaptation component 870 is also configured to perform the second part of the MU-MIMO rate adaptation mechanism for those MU-PPDUs that are transmitted within the channel sounding interval but subsequent to the first MU-PPDU transmitted after completion of the channel sounding sequence.

The rate adaptation component 870 can include an MCS 871 configured to determine, identify, or select an MCS as part of the MU-MIMO rate adaptation mechanism based at least on the aspects described herein for MCS selection in view of different scenarios or conditions as discussed above. The rate adaptation component 870 can also include an Nss 872 configured to determine, identify, or select a number of spatial streams as part of the MU-MIMO rate adaptation mechanism based at least on the aspects described herein for Nss selection in view of different scenarios or conditions as discussed above.

FIG. 9 illustrates an example of hardware implementation of an STA 115 (e.g., STA2 115-b in FIG. 1) that may be employed within a wireless communication system in which an AP is configured to perform the proposed MU-MIMO rate adaptation mechanism described in connection with the scenarios or conditions discussed above. The hardware components and subcomponents of the STA 115 can be used to communicate with the AP. An implementation of the STA 115 can include a variety of components, some of which have already been described above. For example, the STA 115 can include one or more processors 912 having a modem 914, a memory 916 having applications 975, a transceiver 902 having a receiver 906 and a transmitter 908, an RF front end 988 having LNAs 990, switches 992, filters 996, and Pas 998. These components can communicate with each other through one or more buses 944. Moreover, these components can generally operate in a similar manner as corresponding components and subcomponents described above with respect to FIG. 8.

The communications component 160, which can be implemented in the one or more processors 912 and/or as part of the modem 914, can include a channel sounding component 920 and a rate adaptation component 930.

The channel sounding component 920 can be configured to enable the operations or functions performed by an STA during the channel sounding sequence. For example, the channel sounding component 920 can receive NDPAs (e.g., NDPA 510) and NDPs (e.g., NDP 520) from an AP, and can process those packets as described above in connection with FIG. 5. Moreover, the channel sounding component 920 can transmit a CBF report (e.g., CBF reports 530) back to AP to provide channel information that the AP can use for beamforming operations.

The rate adaptation component 930 can be configured to receive, process, and otherwise handle changes in MCS and Nss that occur as part of the MU-MIMO rate adaptation mechanism perform by the AP. For example, the rate adaptation component 930 can include an MCS 931 configured to handle changes in MCS that occur as a result of the proposed MU-MIMO rate adaptation mechanism described herein. Similarly, the rate adaptation component 930 can include an Nss 932 configured to handle changes in the number of spatial streams that occur as a result of the proposed MU-MIMO rate adaptation mechanism described herein.

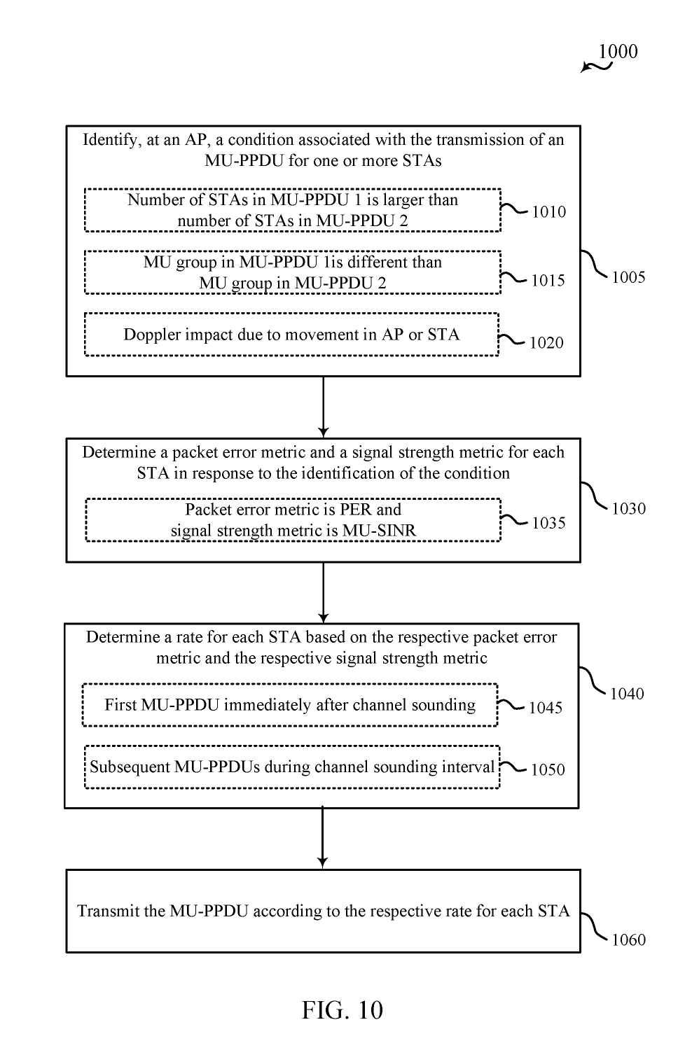

FIG. 10 illustrates an example of a flowchart of a method for wireless communications implemented on an AP in accordance with various aspects of the present disclosure.

At 1005, an AP (e.g., AP1 105-a in FIG. 1) can identify a condition associated with the transmission of an MU-PPDU for one or more STAs. For example, one or more of the processors 812, the memory 816, the modem 814, the communications component 150, or the condition identifying component 820 can be used to identify a condition or scenario as the ones described above, including a first condition when there is a reduced number of STAs in a subsequent MU-PPDU, a second condition related to channel correlation when the MU-MIMO group changes in a subsequent MU-PPDU, and a third condition which involves a joint consideration of the first or second conditions with Doppler impact on the channel.

Optionally at 1010, the AP can identify a first condition. More specifically, the AP can determine that a number of STAs for the MU-PPDU is less than a number of STAs for an immediately preceding or previous MU-PPDU.

Optionally at 1015, the AP can identify a second condition. More specifically, the AP can determine that a first MU-MIMO group comprising the one or more STAs for the MU-PPDU is different from a second MU-MIMO group comprising STAs for an immediately preceding or previous MU-PPDU, where a size of the first MU-MIMO group is the same as a size of the second MU-MIMO group.

Optionally at 1020, the AP can identify a third condition. More specifically, the AP can determine that in addition to the first or second conditions described above, there is a Doppler impact on the channel due to movement in the AP or at least one of the STAs. The Doppler impact can be detected or identified based on the presence of short-term packet error metrics that can be indicative of AP and/or STA movement.

At 1030, the AP can determine a packet error metric and a signal quality metric for each of the STAs in response to the identification of the condition. For example, one or more of the processors 812, the memory 816, the modem 814, the communications component 150, the packet error metric component 830, or the signal quality metric component 850 can be used to determine short-term/instantaneous packet error and signal quality metrics, long-term/historic packet error and signal quality metrics, or both. In an aspect, at 1035, the packet error metric can be PER and the signal quality metric can be MU-SINR.

At 1040, the AP can determine a rate for each of the STAs, or for at least one of the STAs, based on the respective packet error metric and the respective signal quality metric. For example, one or more of the processors 812, the memory 816, the modem 814, the communications component 150, or the rate adaptation component 870 can be used to determine the rate of one or more of the STAs. In an aspect, the MCS 871 in the rate adaptation component 870 can be used to determine the rate of an STA by selecting an appropriate MCS for that STA. Similarly, the Nss 872 in the rate adaptation component 870 can be used to determine the rate of an STA by selecting an appropriate number of spatial streams for that STA. In an aspect, determining the rate for an STA can involve identifying that a current rate, that is, a current MCS and Nss, is still appropriate for a subsequent MU-PPDU and that no change to the current MCS and Nss is necessary.

Optionally at 1045, a first part of the rate adaptation of 1040 applies to the first MU-PPDU immediately after the channel sounding sequence is completed. This first part corresponds to a first part of the MU-MIMO rate adaptation mechanism described herein and can be implemented using different approaches (see e.g., methods 600 and 700 in FIGS. 6 and 7, respectively).

Optionally at 1050, a second part of the rate adaptation of 1040 applies to any MU-PPDU that is subsequent to the first MU-PPDU within the channel sounding interval.

At 1060, the AP can transmit the MU-PPDU according to the respective rate for each of the STAs. For example, one or more of the processors 812, the memory 816, the modem 814, the communications component 150, the rate adaptation component 870, the transceiver 802, or the RF front end 888 can be used to transmit the MU-PPDU according to the rates (e.g., MCS, Nss) for each of the STAs to be joined in the MU-PPDU.

Referring to FIGS. 6-10, aspects of the present hardware implementations and methods are depicted with reference to one or more components or subcomponents, and one or more methods, which can perform the actions or functions described herein. Although the operations or methods described above in FIGS. 6, 7, and 10 are presented in a particular order and/or as being performed by an example component, it should be understood that the ordering of the actions and the components performing the actions may be varied, depending on the implementation. Moreover, it should be understood that the actions or functions can be performed by a specially-programmed or specially-configured processor, a processor executing specially-programmed software or computer-readable media, or by any other combination of a hardware component and/or a software component capable of performing the described actions or functions. Moreover, in an aspect, a component may be one of the parts that make up a system, may be hardware or software, and/or may be divided into other components (e.g., subcomponents).

By way of example, an element or component, or any portion of an element or component, or any combination of elements or components can be implemented with a “processing system” that includes one or more processors. A processor can include a general purpose processor, a digital signal processor (DSP), an application specific integrated circuit (ASIC), a field programmable gate array (FPGA) or other programmable logic component, discrete gate or transistor logic, discrete hardware components, or any combination thereof, or any other suitable component designed to perform the functions described herein. A general-purpose processor may be a microprocessor, but in the alternative, the processor may be any conventional processor, controller, microcontroller, or state machine. A processor may also be implemented as a combination of computing components, e.g., a combination of a DSP and a microprocessor, a plurality of microprocessors, one or more microprocessors in conjunction with a DSP, or any other such configuration.

One or more processors in the processing system may execute software. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may reside on transitory or non-transitory computer-readable medium. A non-transitory computer-readable medium may include, by way of example, a magnetic storage device (e.g., hard disk, floppy disk, magnetic strip), an optical disk (e.g., compact disk (CD), digital versatile disk (DVD)), a smart card, a flash memory device (e.g., card, stick, key drive), random access memory (RAM), static RAM (SRAM), dynamic RAM (DRAM), synchronous dynamic RAM (SDRAM); double date rate RAM (DDRAM), read only memory (ROM), programmable ROM (PROM), erasable PROM (EPROM), electrically erasable PROM (EEPROM), a general register, or any other suitable non-transitory medium for storing software.

The various interconnections within a processing system may be shown as buses or as single signal lines. Each of the buses may alternatively be a single signal line, and each of the single signal lines may alternatively be buses, and a single line or bus might represent any one or more of a myriad of physical or logical mechanisms for communication between elements. Any of the signals provided over various buses described herein may be time-multiplexed with other signals and provided over one or more common buses.

The various aspects of this disclosure are provided to enable one of ordinary skill in the art to practice the present disclosure. Various modifications to examples of implementations presented throughout this disclosure will be readily apparent to those skilled in the art, and the concepts disclosed herein may be extended to other devices, systems, or networks. Thus, the claims are not intended to be limited to the various aspects of this disclosure, but are to be accorded the full scope consistent with the language of the claims. All structural and functional equivalents to the various components of the examples of implementations described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112 (f), unless the element is expressly recited using the phrase “means for” or, in the case of a method claim, the element is recited using the phrase “step for.”

What is claimed is:

1. A method of multi-user multiple-input-multiple-output (MU-MIMO) communications, comprising:
identifying, at an access point (AP), a condition associated with the transmission of an MU PLCP Protocol Data Unit (MU-PPDU) for multiple stations (STAs);
determining a packet error metric and a signal quality metric for each of the STAs in response to the identification of the condition;
determining a rate for each of the STAs based on the respective packet error metric and the respective signal quality metric; and
transmitting the MU-PPDU according to the respective rate for each of the STAs.

2. The method of claim 1, wherein the packet error metric is a packet error rate (PER) and the signal quality metric is a signal-to-interference-plus-noise ratio (SINR).

3. The method of claim 1, wherein determining the rate for each of the STAs includes determining one or both of a modulation coding scheme (MCS) or a number of spatial streams (Nss).

4. The method of claim 1, wherein identifying the condition includes determining that a number of STAs for the MU-PPDU is less than a number of STAs for an immediately preceding MU-PPDU.

5. The method of claim 4, wherein identifying the condition further includes determining a Doppler impact on a channel for the transmission of the MU-PPDU.

6. The method of claim 1, wherein identifying the condition includes determining that a first MU-MIMO group comprising the STAs for the MU-PPDU is different from a second MU-MIMO group comprising STAs for an immediately preceding MU-PPDU, and wherein a size of the first MU-MIMO group is the same as a size of the second MU-MIMO group.

7. The method of claim 6, wherein identifying the condition further includes determining a Doppler impact on a channel for the transmission of the MU-PPDU.

8. The method of claim 1, further comprising:
performing a channel sounding sequence;
wherein the MU-PPDU is a first MU-PPDU transmitted immediately after performing the channel sounding sequence,
wherein determining the packet error metric for each of the STAs of the first MU-PPDU includes determining a long-term packet error metric, and
wherein determining the rate for each of the STAs of the first MU-PPDU based on the respective packet error metric includes determining the rate based on the respective long-term packet error metric.

9. The method of claim 8, wherein determining the signal quality metric for each of the STAs of the first MU-PPDU includes estimating the signal quality metric based at least in part on a corresponding compressed beamforming (CBF) report received by the AP in response to the channel sounding sequence.

10. The method of claim 1, further comprising:
performing a channel sounding sequence;
wherein the MU-PPDU is a subsequent MU-PPDU to the first MU-PPDU transmitted immediately after performing the channel sounding sequence,
wherein determining the packet error metric for each of the STAs of the subsequent MU-PPDU includes determining a short-term packet error metric based at least in part on a block acknowledgement associated with an earlier MU-PPDU, and
wherein determining the rate for each of the STAs of the subsequent MU-PPDU based on the respective packet error metric includes determining the rate based on the respective short-term packet error metric.

11. The method of claim 1, wherein determining the rate for each of the STAs includes:
weighting the respective packet error metric for each of the STAs;
weighting the respective signal quality metric for each of the STAs; and
determining an MCS for each of the STAs based on the respective weighted packet error metric and the respective weighted signal quality metric.

12. The method of claim 1, wherein:
determining the packet error metric for each of the STAs includes determining a short-term packet error metric and a long-term packet error metric, and
determining the rate for each of the STAs includes determining an MCS based at least in part on the respective short-term packet error metric, the respective long-term packet error metric, and the respective signal quality metric.

13. An apparatus for multi-user multiple-input-multiple-output (MU-MIMO) communications, comprising:
a memory that stores MU-MIMO communications instructions; and
a processor coupled with the memory, and configured to execute the MU-MIMO communications instructions to:
identify, at an access point (AP), a condition associated with the transmission of an MU PLCP Protocol Data Unit (MU-PPDU) for multiple wireless stations (STAs);
determine a packet error metric and a signal quality metric for each of the STAs in response to the identification of the condition;
determine a rate for each of the STAs based on the respective packet error metric and the respective signal quality metric; and
transmit the MU-PPDU according to the respective rate for each of the STAs.

14. The apparatus of claim 13, wherein the packet error metric is a packet error rate (PER) and the signal quality metric is a signal-to-interference-plus-noise ratio (SINR).

15. The apparatus of claim 13, wherein the processor is configured to determine the rate for each of the STAs by determining one or both of a modulation coding scheme (MCS) or a number of spatial streams (Nss).

16. The apparatus of claim 13, wherein the processor is configured to identify the condition by determining that a number of STAs for the MU-PPDU is less than a number of STAs for an immediately preceding MU-PPDU.

17. The apparatus of claim 16, wherein the processor is configured to identify the condition by further determining a Doppler impact on a channel for the transmission of the MU-PPDU.

18. The apparatus of claim 13, wherein the processor is configured to identify the condition by determining that a first MU-MIMO group comprising the STAs for the MU-PPDU is different from a second MU-MIMO group comprising STAs for an immediately preceding MU-PPDU, and wherein a size of the first MU-MIMO group is the same as a size of the second MU-MIMO group.

19. The apparatus of claim 18, wherein the processor is configured to identify the condition by further determining a Doppler impact on a channel for the transmission of the MU-PPDU.

20. The apparatus of claim 13, wherein the processor is further configured to:
perform a channel sounding sequence;
wherein the MU-PPDU is a first MU-PPDU transmitted immediately after performing the channel sounding sequence,
wherein the processor is configured to determine the packet error metric for each of the STAs of the first MU-PPDU by determining a long-term packet error metric, and
wherein the processor is configured to determine the rate for each of the STAs of the first MU-PPDU based on the respective packet error metric by determining the rate based on the respective long-term packet error metric.

21. The apparatus of claim 20, wherein the processor is configured to determine the signal quality metric for each of the STAs of the first MU-PPDU by estimating the signal quality metric based at least in part on a corresponding compressed beamforming (CBF) report received by the AP in response to the channel sounding sequence.

22. The apparatus of claim 13, wherein the processor is further configured to:
perform a channel sounding sequence;
wherein the MU-PPDU is a subsequent MU-PPDU to the first MU-PPDU transmitted immediately after performing the channel sounding sequence,
wherein the processor is configured to determine the packet error metric for each of the STAs of the subsequent MU-PPDU by determining a short-term packet error metric based at least in part on a block acknowledgement associated with an earlier MU-PPDU, and
wherein the processor is configured to determine the rate for each of the STAs of the subsequent MU-PPDU based on the respective packet error metric by determining the rate based on the respective short-term packet error metric.

23. The apparatus of claim 13, wherein the processor is configured to determine the rate for each of the STAs by:
weighting the respective packet error metric for each of the STAs;
weighting the respective signal quality metric for each of the STAs; and
determining an MCS for each of the STAs based on the respective weighted packet error metric and the respective weighted signal quality metric.

24. The apparatus of claim 13, wherein the processor is configured to:
determine the packet error metric for each of the STAs by determining a short-term packet error metric and a long-term packet error metric, and
determine the rate for each of the STAs by determining an MCS based at least in part on the respective short-term packet error metric, the respective long-term packet error metric, and the respective signal quality metric.

25. An apparatus for multi-user multiple-input-multiple-output (MU-MIMO) communications, comprising:
means for identifying, at an access point (AP), a condition associated with the transmission of an MU PLCP Protocol Data Unit (MU-PPDU) for multiple wireless stations (STAs);
means for determining a packet error metric and a signal quality metric for each of the STAs in response to the identification of the condition;
means for determining a rate for each of the STAs based on the respective packet error metric and the respective signal quality metric; and
means for transmitting the MU-PPDU according to the respective rate for each of the STAs.

26. The apparatus of claim 25, wherein the means for identifying the condition includes means for determining that a number of STAs for the MU-PPDU is less than a number of STAs for an immediately preceding MU-PPDU.

27. The apparatus of claim 25, wherein the means for identifying the condition includes means for determining that a first MU-MIMO group comprising the STAs for the MU-PPDU is different from a second MU-MIMO group comprising STAs for an immediately preceding MU-PPDU, and wherein a size of the first MU-MIMO group is the same as a size of the second MU-MIMO group.

28. The apparatus of claim 25, wherein the means for identifying the condition includes:
means for determining a Doppler impact on a channel for the transmission of the MU-PPDU, and one of:
means for determining that a number of STAs for the MU-PPDU is less than a number of STAs for an immediately preceding MU-PPDU, or
means for determining that a first MU-MIMO group comprising the STAs for the MU-PPDU is different from a second MU-MIMO group comprising STAs for an immediately preceding MU-PPDU, and wherein a size of the first MU-MIMO group is the same as a size of the second MU-MIMO group.

29. The apparatus of claim 25, wherein the packet error metric is a packet error rate (PER) and the signal quality metric is a signal-to-interference-plus-noise ratio (SINR).

30. A computer-readable medium storing executable code for multi-user multiple-input-multiple-output (MU-MIMO) communications, comprising:
code for identifying, at an access point (AP), a condition associated with the transmission of an MU PLCP Protocol Data Unit (MU-PPDU) for multiple wireless stations (STAs);
code for determining a packet error metric and a signal quality metric for each of the STAs in response to the identification of the condition;
code for determining a rate for each of the STAs based on the respective packet error metric and the respective signal quality metric; and
code for transmitting the MU-PPDU according to the respective rate for each of the STAs.
